(19) United States
(12) Patent Application Publication
(10) Pub. No.: US 2024/0213250 A1
(43) Pub. Date: Jun. 27, 2024

(54) SELF-ALIGNED BACKBONE FOR FORKSHEET TRANSISTORS

(71) Applicant: INTEL CORPORATION, SANTA CLARA, CA (US)

(72) Inventors: Shao Ming KOH, Tigard, OR (US); Sudipto NASKAR, Portland, OR (US); Leonard P. GULER, Hillsboro, OR (US); Patrick MORROW, Portland, OR (US); Richard E. SCHENKER, Portland, OR (US); Walid M. HAFEZ, Portland, OR (US); Charles H. WALLACE, Portland, OR (US); Mohit K. HARAN, Hillsboro, OR (US); Jeanne L. LUCE, Hillsboro, OR (US); Dan S. LAVRIC, Beaverton, OR (US); Jack T. KAVALIEROS, Portland, OR (US); Matthew PRINCE, Portland, OR (US); Lars LIEBMANN, Mechanicville, NY (US)

(21) Appl. No.: 18/088,547

(22) Filed: Dec. 24, 2022

(51) Int. Cl. H01L 27/092; H01L 29/06; H01L 29/786

(52) U.S. Cl. CPC H01L 27/0924; H01L 29/0673; H01L 29/78696

(57) ABSTRACT

Embodiments disclosed herein include forksheet transistor transistors with self-aligned backbones. In an example, an integrated circuit structure includes a backbone including a lower backbone portion distinct from an upper backbone portion. A first vertical stack of nanowires is in lateral contact with a first side of the backbone. A second vertical stack of nanowires is in lateral contact with a second side of the backbone, the second side opposite the first side.

### TECHNICAL FIELD

Embodiments of the present disclosure relate to integrated circuit structures, and more particularly to forksheet transistors with self-aligned backbones, and methods of fabricating forksheet transistors with self-aligned backbones.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

In the manufacture of integrated circuit devices, multi-gate transistors, such as tri-gate transistors, have become more prevalent as device dimensions continue to scale down. In conventional processes, tri-gate transistors are generally fabricated on either bulk silicon substrates or silicon-on-insulator substrates. In some instances, bulk silicon substrates are preferred due to their lower cost and because they enable a less complicated tri-gate fabrication process. In another aspect, maintaining mobility improvement and short channel control as microelectronic device dimensions scale below the 10 nanometer (nm) node provides a challenge in device fabrication. Nanowires used to fabricate devices provide improved short channel control.

Scaling multi-gate and nanowire transistors has not been without consequence, however. As the dimensions of these fundamental building blocks of microelectronic circuitry are reduced and as the sheer number of fundamental building blocks fabricated in a given region is increased, the constraints on the lithographic processes used to pattern these building blocks have become overwhelming. In particular, there may be a trade-off between the smallest dimension of a feature patterned in a semiconductor stack (the critical dimension) and the spacing between such features.

### BRIEF DESCRIPTION OF THE DRAWINGS

FIG. 1A is a perspective view illustration of forksheet transistors, in accordance with an embodiment.

FIG. 1B is a cross-sectional illustration of forksheet transistors across the semiconductor channels, in accordance with an embodiment.

FIGS. 2A-2F illustrate cross-sectional views representing various operation in a method of fabricating forksheet transistors with self-aligned backbones, in accordance with an embodiment of the present disclosure.

FIGS. 3A-3H illustrate angled cross-sectional views representing various operation in a method of fabricating forksheet transistors with self-aligned backbones, in accordance with an embodiment of the present disclosure.

FIG. 4A is a cross-sectional illustration of a transistor with a plurality of stacked semiconductor channels, in accordance with an embodiment.

FIG. 4B is a cross-sectional illustration of the transistor in FIG. 4A, along line 1-1′, in accordance with an embodiment.

FIG. 4C is a cross-sectional illustration of a transistor with a depopulated channel, in accordance with an embodiment.

FIG. 4D is a cross-sectional illustration of a transistor with two depopulated channels, in accordance with an embodiment.

FIG. 5A is a cross-sectional illustration of transistor after source/drain regions are formed, in accordance with an embodiment.

FIG. 5B is a cross-sectional illustration of the transistor in FIG. 5A along line 2-2′, in accordance with an embodiment.

FIG. 5C is a cross-sectional illustration of the transistor after a sacrificial gate is removed, in accordance with an embodiment.

FIG. 5D is a cross-sectional illustration of the transistor after a pre-amorphization process is implemented on the top channel, in accordance with an embodiment.

FIG. 5E is a cross-sectional illustration of the transistor after a dopant is selectively implanted into the top channel, in accordance with an embodiment.

FIG. 5F is a cross-sectional illustration of the transistor after the sacrificial layers between the channels are removed, in accordance with an embodiment.

FIG. 5G is a cross-sectional illustration of the transistor after a gate dielectric is disposed around the channels, in accordance with an embodiment.

FIG. 5H is a cross-sectional illustration of the transistor after a gate electrode is disposed around the gate dielectric, in accordance with an embodiment.

FIGS. 6A-6C are cross-sectional illustrations of an integrated circuit device that includes a first transistor and a second transistor, where the number of active channels is different between the two transistors, in accordance with various embodiments.

FIG. 7A is a cross-sectional illustration of a transistor with a depopulated region below a stack of channels, in accordance with an embodiment.

FIG. 7B is a cross-sectional illustration of a transistor with a pair of depopulated region below a stack of channels, in accordance with an embodiment.

FIGS. 8A-8D are cross-sectional illustrations of a process for forming a depopulated region in a stack of channels, in accordance with an embodiment.

FIG. 9A-9E are cross-sectional illustrations of integrated circuit devices that include a first transistor and a second transistor, where the number of active channels is different between the two transistors, in accordance with various embodiments.

FIG. 10 illustrates a computing device in accordance with one implementation of an embodiment of the disclosure.

FIG. 11 is an interposer implementing one or more embodiments of the disclosure.

### EMBODIMENTS OF THE PRESENT DISCLOSURE

Described herein are forksheet transistors with self-aligned backbones, and methods of fabricating forksheet transistors with self-aligned backbones, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions or context for terms found in this disclosure (including the appended claims):

“Comprising.” This term is open-ended. As used in the appended claims, this term does not foreclose additional structure or operations.

“Configured To.” Various units or components may be described or claimed as “configured to” perform a task or tasks. In such contexts, “configured to” is used to connote structure by indicating that the units or components include structure that performs those task or tasks during operation. As such, the unit or component can be said to be configured to perform the task even when the specified unit or component is not currently operational (e.g., is not on or active). Reciting that a unit or circuit or component is “configured to” perform one or more tasks is expressly intended not to invoke 35 U.S.C. § 112, sixth paragraph, for that unit or component.

“First,” “Second,” etc. As used herein, these terms are used as labels for nouns that they precede, and do not imply any type of ordering (e.g., spatial, temporal, logical, etc.).

“Coupled.” The following description refers to elements or nodes or features being “coupled” together. As used herein, unless expressly stated otherwise, “coupled” means that one element or node or feature is directly or indirectly joined to (or directly or indirectly communicates with) another element or node or feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation or location or both of portions of the component within a consistent but arbitrary frame of reference which is made clear by reference to the text and the associated drawings describing the component under discussion. Such terminology may include the words specifically mentioned above, derivatives thereof, and words of similar import.

“Inhibit.” As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, or effect which might otherwise occur. Accordingly, when a component, element, or feature is referred to as inhibiting a result or state, it need not completely prevent or eliminate the result or state.

Embodiments described herein may be directed to front-end-of-line (FEOL) semiconductor processing and structures. FEOL is the first portion of integrated circuit (IC) fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may be directed to back-end-of-line (BEOL) semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

One or more embodiments described herein are directed to a self-aligned cut process for wall or backbone formation in a Forksheet architecture. It is to be appreciated that, unless specified otherwise, reference to a nanowire can refer to a nanowire, a nanoribbon, or even a nanosheet.

To provide context, in order to combat the demands of spacing between features, a forksheet transistor architecture has been proposed. In a forksheet architecture, an insulating backbone is disposed between a first transistor and a second transistor. The semiconductor channels (e.g., ribbons, wires, etc.) of the first transistor and the second transistor contact opposite sidewalls of the backbone. As such, the spacing between the first transistor and the second transistor is reduced to the width of the backbone. Since one surface of the semiconductor channels contacts the backbone, such architectures do not allow for gate-all-around (GAA) control of the semiconductor channels. Additionally, compact interconnect architectures between the first transistor and the second transistor have yet to be proposed.

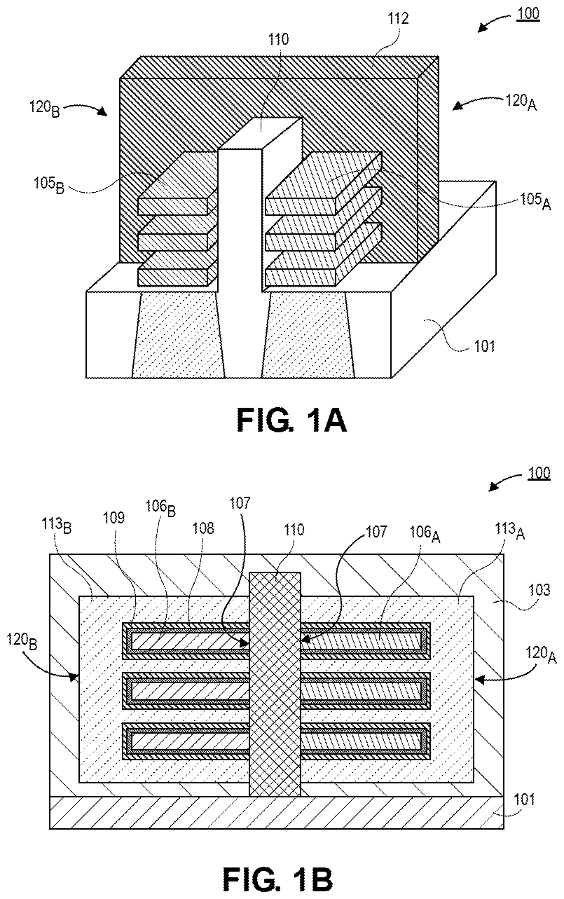

As noted above, forksheet transistors allow for increased density of non-planar transistor devices. An example of semiconductor device 100 with forksheet transistors 120A and 120B is shown in FIG. 1A. A forksheet transistor includes a backbone 110 that extends up from a substrate 101 with a transistor 120 adjacent to the either sidewall of the backbone 110. As such, the spacing between transistors 120A and 120B is equal to the width of the backbone 110. Therefore, the density of such forksheet transistors 120 can be increased compared to other non-planar transistor architectures (e.g., fin-FETs, nanowire transistors, etc.).

Sheets 105 of semiconductor material extend away (laterally) from the backbone 110. In the illustration of FIG. 1A, sheets 105A and 105B are shown on either side of the backbone 110. The sheets 105A are for the first transistor 120A and the sheets 105B are for the second transistor 120B. The sheets 105A and 105B pass through a gate structure 112. The portions of the sheets 105A and 105B within the gate structure 112 are considered the channel, and the portions of the sheets 105A and 105B on opposite sides of the gate structure 112 are considered source/drain regions. In some implementations, the source/drain regions include an epitaxially grown semiconductor body, and the sheets 105 may only be present within the gate structure 112. That is, the stacked sheets 105A and 105B are replaced with a block of semiconductor material.

Referring now to FIG. 1B, a cross-sectional illustration of the semiconductor device 100 through the gate structure 112 is shown. As shown, vertical stacks of semiconductor channels 106A and 106B are provided through the gate structure 112. The semiconductor channels 106A and 106B are connected out of the plane of FIG. 1B to the source/drain regions. The semiconductor channels 106A and 106B are surrounded on three sides by a gate dielectric 108. The surfaces 107 of the semiconductor channels 106A and 106B are in direct contact with the backbone 110. A workfunction metal 109 may surround the gate dielectric 108, and a gate fill metal 113A and 113B may surround the workfunction metal 109. In the illustration, the semiconductor channels 106A and 106B are shown as having different shading. However, in some implementations, the semiconductor channels 106A and 106B may be the same material. An insulator layer 103 may be disposed over the gate fill metals 113A and 113B.

While such forksheet transistors 120A and 120B provide many benefits, there are still many areas for improvement in order to provide higher densities, improved interconnection architectures, and improved performance. For example, embodiments disclosed herein provide further density improvements by stacking a plurality of transistor strata over each other. Whereas the semiconductor device 100 in FIGS. 1A and 1B illustrate a single strata (i.e., a pair of adjacent forksheet transistors 120A and 120B), embodiments disclosed herein include a first strata and a second strata (e.g., to provide four forksheet transistors) within the same footprint illustrated in FIGS. 1A and 1B. Additionally, embodiments disclosed herein provide interconnect architectures that allow for electrical coupling between the first strata and the second strata to effectively utilize the multiple strata. Additionally, embodiments disclosed herein include interconnect architectures that allow for bottom side connections to the buried strata.

In an embodiment a material for a backbone may be composed of a material suitable to ultimately electrically isolate, or contribute to the isolation of, active regions of neighboring transistor devices. For example, in one embodiment, a backbone is composed of a dielectric material such as, but not limited to, silicon dioxide, silicon oxy-nitride, silicon nitride, or carbon-doped silicon nitride. In an embodiments, a backbone is composed of or includes a dielectric such as an oxide of silicon (e.g., silicon dioxide (SiO₂)), a doped oxide of silicon, a fluorinated oxide of silicon, a carbon doped oxide of silicon, a low-k dielectric material known in the art, and combinations thereof. The backbone material may be formed by a technique, such as, for example, chemical vapor deposition (CVD), physical vapor deposition (PVD), or by other deposition methods.

To provide further context, continued scaling of cell height pushes the spacing between NFET and PFET. Process challenges can pose a limit on how close these transistors can be placed from each other. The use of a dielectric wall to separate N and PFET allows further N-P space scaling and further increase in the active area width for a given footprint of a cell design.

To enable the above architecture, conventional method uses spacer patterning to form fins close to each other followed by dielectric fill in between the fins to create the dielectric wall. However, this method can limit the minimum fin width supportable. Fins may need to be printed at a wider dimension to account for critical dimension (CD) loss from both sides during subsequent steps. This can reduce the spacing in between the fins, making gapfill difficult. Additionally, tall and thin starting fins can also pose risk of fin bending.

In accordance with one or more embodiments of the present disclosure, a self-aligned cut process is to create a dielectric backbone or wall. The dielectric backbone or wall can function as a metal gate separation structure for split gate transistors, addressing issues described above.

In accordance with one or more embodiments of the present disclosure, a cut process is used to create both a dielectric wall and associated fins. For example, wider starting fins can be printed using direct patterning instead of multiple spacer patterning operations. This approach can minimize creation of narrow starting fins which pose fin bending risks. A self-aligned cut process can later define the spacing of the dielectric wall prior to dielectric fill. The self-aligned dielectric backbone or wall can function as a self-aligned separation between NMOS and PMOS split gate transistors.

The implementation of embodiments described herein may be detectable by the presence of a dielectric wall separating N and P fins/ribbons with the same dimension and pitch. Fin CD and spacing definition with spacer patterning may not allow small fin pitch with narrow space to be formed as fin CD loss has to be accounted for. As the dielectric wall spacing and the fin are created in separate operations, the dielectric wall bottom and the fin bottom can be at different level.

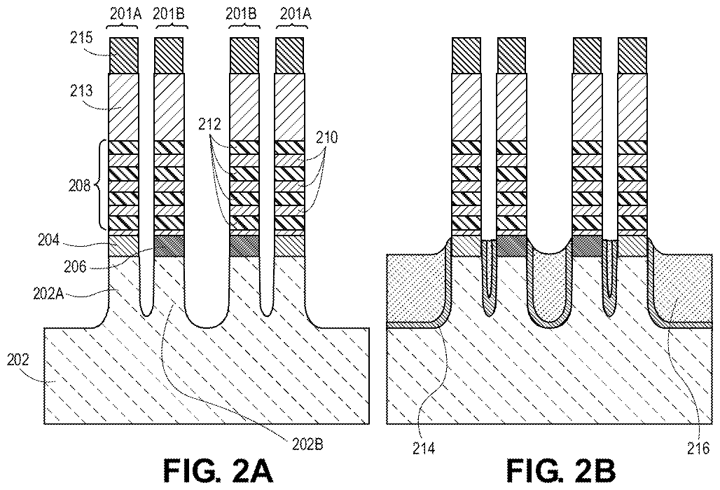

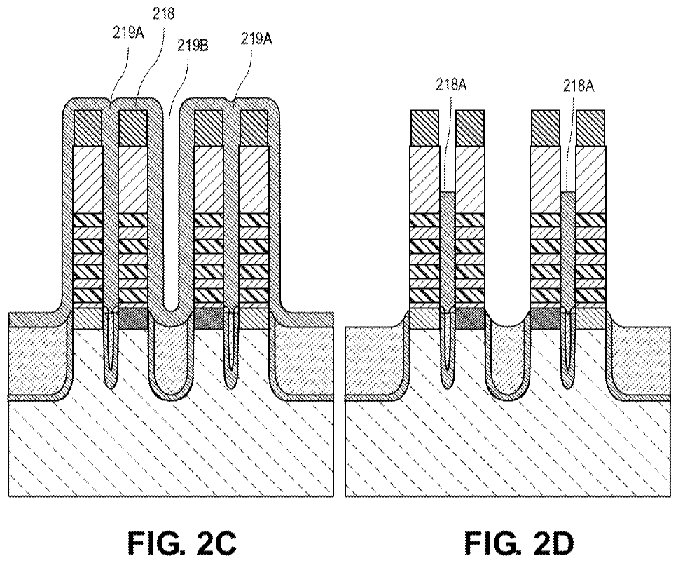

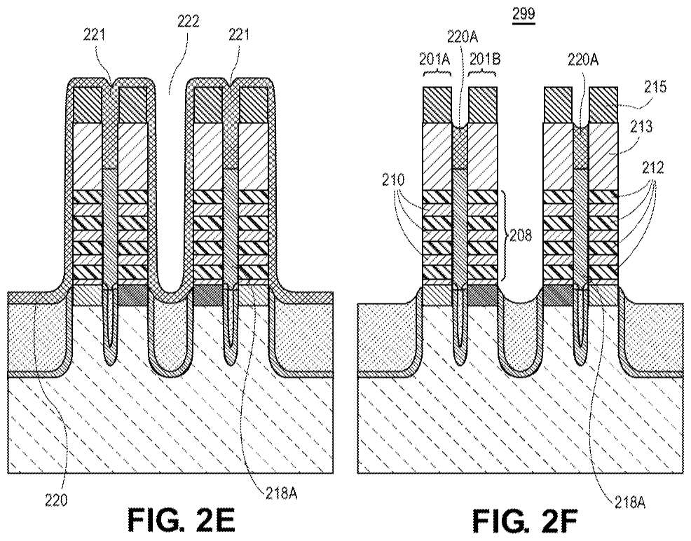

Thus, a backbone or wall for a forksheet structure can be fabricated in a self-aligned manner. In an example, FIGS. 2A-2F illustrate cross-sectional views representing various operation in a method of fabricating forksheet transistors with self-aligned backbones, in accordance with an embodiment of the present disclosure.

Referring to FIG. 2A, a starting structure includes a plurality of fins 201A and 201B extending from a substrate 202. Each of the fins 201A/201B includes a sub-fin structure 202A or 202B, such as a silicon sub-fin structure. A well 204 or 206 is in the sub-fin structure 202A or 202B. A stack 208 of alternating nanowires or nanoribbons 210 and sacrificial layers 212, such as silicon nanowires or nanoribbons 210 and silicon germanium sacrificial layers 212 is above a corresponding sub-fin structure 202A or 202B. A dielectric cap 213, such as a silicon nitride cap and a hardmask 215 are on each of the stacks 208.

In an embodiment, fins 201A will ultimately be used to fabricate an NMOS device, and wells 204 are P-wells, while fins 201B will ultimately be used to fabricate a PMOS device, and wells 206 are N-wells. In another embodiment, fins 201B will ultimately be used to fabricate an NMOS device, and wells 206 are P-wells, while fins 201A will ultimately be used to fabricate a PMOS device, and wells 204 are N-wells.

Referring to FIG. 2B, isolation structures such as shallow trench isolation (STI) structures are formed between adjacent ones of the fins 201A and 201B. In one embodiment, the isolation structures are formed by depositing and then recessing a dielectric liner 214 and a dielectric fill 216, such as a silicon nitride dielectric liner and a silicon oxide or silicon dioxide dielectric fill.

Referring to FIG. 2C, a first backbone-forming layer 218, such as a silicon nitride layer, is formed on the structure of FIG. 2B. The first backbone-forming layer 218 is closed at tightly-spaced fin locations 219A, and is open at widely-spaced fin locations 219B.

Referring to FIG. 2D, the first backbone-forming layer 218 is exposed to an etch process to remove all portions of the first backbone-forming layer 218 except at locations 219A. The portions of the first backbone-forming layer 218 retained at locations 219A form lower backbone portions 218A.

Referring to FIG. 2E, a second backbone-forming layer 220, such as a silicon oxide or silicon dioxide layer, is formed on the structure of FIG. 2D. The second backbone-forming layer 220 is closed at tightly-spaced fin locations 221, and is open at widely-spaced fin locations 222. In another embodiment, lower backbone portions 218A are composed of silicon, oxygen and nitrogen, and second backbone-forming layer 220 is composed of hafnium and oxygen.

Referring to FIG. 2F, the second backbone-forming layer 220 is exposed to an etch process to remove all portions of the second backbone-forming layer 220 except at locations 221 to form structure 299. The portions of the second backbone-forming layer 220 retained at locations 221 form upper backbone portions 220A. The combination of each lower backbone portion 218A and the overlying corresponding upper backbone portion 220A forms a forksheet backbone 218A/220A.

It is to be appreciated that the structure 299 can be subjected to subsequent processing to form forksheet structures, such as a first forksheet structure formed from the two left-hand fins 201A/201B, and a second forksheet structure formed from the two right-hand fins. Subsequent processing can include nanowire or nanoribbon 210 release by removing the sacrificial layers 212. The hardmask 215 can be removed, and the dielectric cap 213 can be retained or removed. A gate structure can be formed around each corresponding stack of released nanowires or nanoribbons 210. In one embodiment, the forksheet backbone 218A/220A is higher than the gate structures, and the forksheet backbone 218A/220A acts as an endcap for the gate structures, such as is depicted in FIG. 1B.

Referring again to FIG. 2F, an integrated circuit structure 299 includes a backbone 218A/220A including a lower backbone portion 218A distinct from an upper backbone portion 220A. A first vertical stack of nanowires 210 is in lateral contact with a first side of the backbone 218A/220A. A second vertical stack of nanowires 210 is in lateral contact with a second side of the backbone 218A/220A, the second side opposite the first side.

In an embodiment, a seam is vertically between the lower backbone portion 218A distinct and the upper backbone portion 220A, as is depicted. In an embodiment, the lower backbone portion 218A includes silicon and nitrogen, and the upper backbone portion 220A includes silicon and oxygen.

In an embodiment, the first and second vertical stacks of nanowires 210 are in lateral contact with the lower backbone portion 218A but not with the upper backbone portion 220A, as is depicted. In another embodiment, however, the first and second vertical stacks of nanowires 210 are in lateral contact with both the lower backbone portion 218A and the upper backbone portion 220A.

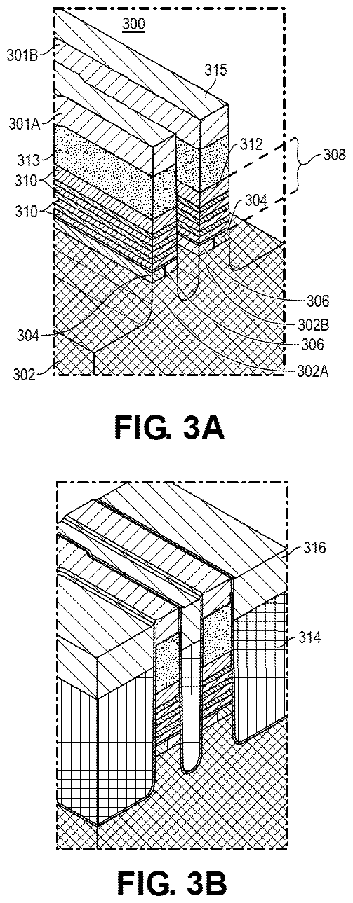

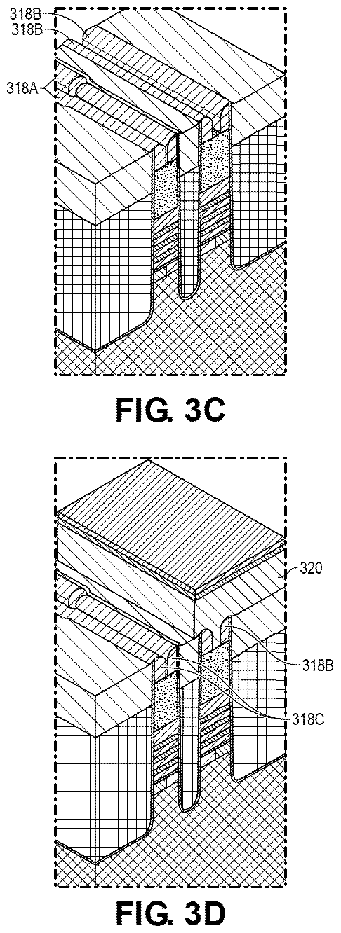

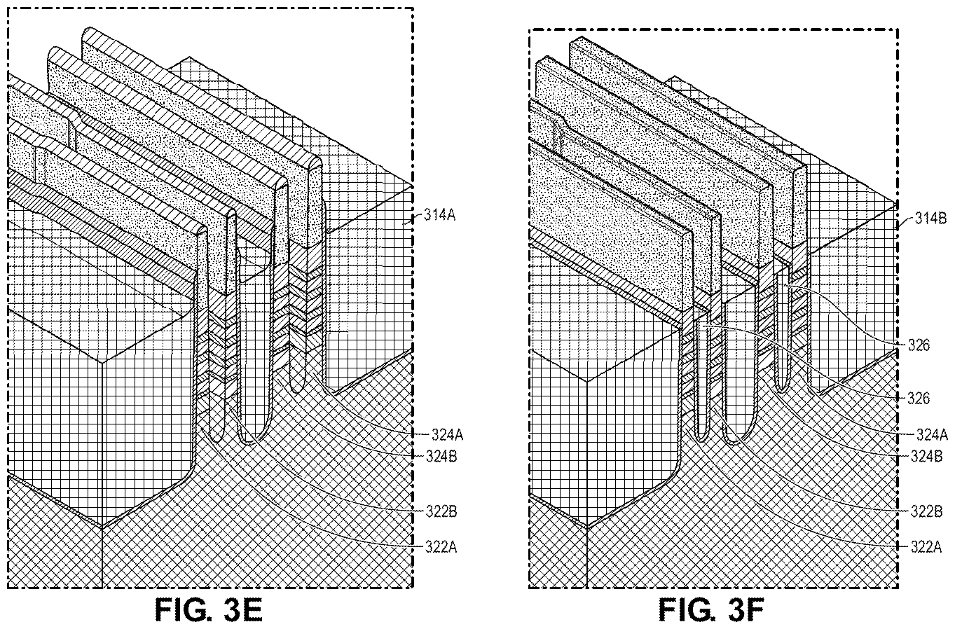

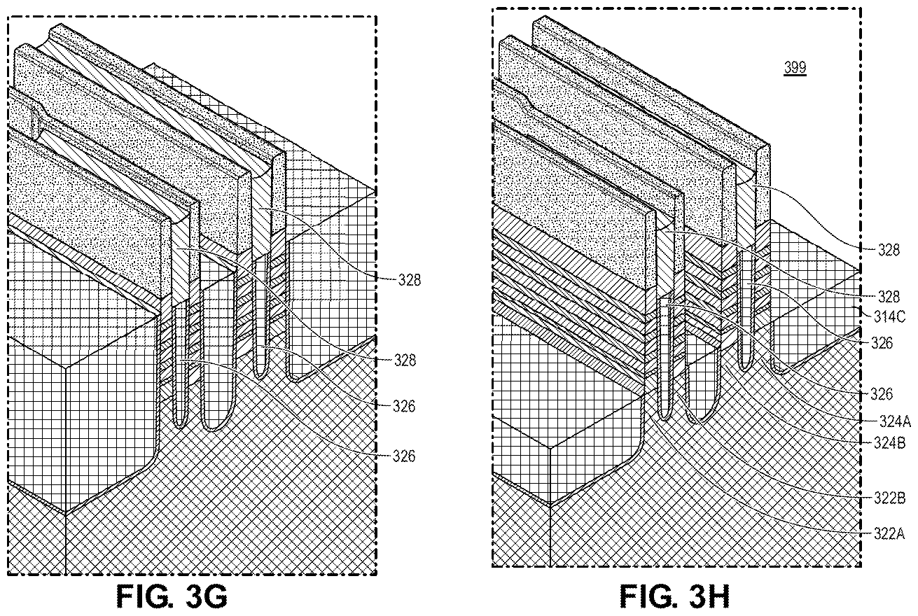

In another example a process begins with relatively wider fins followed by a self-aligned cut and then formation of a backbone or wall for a forksheet structure. In an example, FIGS. 3A-3H illustrate angled cross-sectional views representing various operation in a method of fabricating forksheet transistors with self-aligned backbones, in accordance with an embodiment of the present disclosure.

Referring to FIG. 3A, a starting structure includes fins 301A and 301B extending from a substrate 302. The fin 301A is a relatively narrower fin, and the fin 301B is a relatively wider fin. Each of the fins 301A/301B includes a sub-fin structure 302A or 302B, such as a silicon sub-fin structure. Wells 304 and 306 are in each sub-fin structure 302A or 302B. A stack 308 of alternating nanowires or nanoribbons 310 and sacrificial layers 312, such as silicon nanowires or nanoribbons 310 and silicon germanium sacrificial layers 312 is above a corresponding sub-fin structure 302A or 302B. A dielectric cap 313, such as a silicon nitride cap and a hardmask 315 are on each of the stacks 308.

In an embodiment, fins 301A and 301B will each ultimately be used to fabricate both an NMOS device and a PMOS device. In one embodiment, wells 304 are P-wells, and wells 306 are N-wells. In another embodiment, wells 306 are P-wells, and wells 304 are N-wells.

Referring to FIG. 3B, isolation structures 314, such as silicon oxide or dioxide structures, and a hardmask 316, such as a silicon nitride hardmask, are formed adjacent to the fins 301A and 301B.

Referring to FIG. 3C, hardmask 315 is removed from fins 301A and 301B. Patterning spacers 318A and 318B are formed in the location previously occupied by hardmask 315.

Referring to FIG. 3D, the patterning spacers 318B are masked with a mask 320, and the patterning spacers 318A are trimmed to form patterning spacers 318C for the relatively narrow fin. The patterning spacers 318B and 318C provide a similar CD opening over the corresponding fins.

Referring to FIG. 3E, the fins are etched using the patterning spacers 318B and 318C as a mask. The etching forms relatively narrow fins 322A and 322B, and relatively wide fins 324A and 324B. The etch process can also remove the hardmask 316 and can recess the isolation structures 314 to form recessed isolation structures 314A.

Referring to FIG. 3F, the patterning spacers 318B and 318C are removed, and the recessed isolation structures 314A are further recessed to form recessed isolation structures 314B. The recessed isolation structures 314B include lower backbone portions 326.

Referring to FIG. 3G, upper backbone portions 328 are formed on the lower backbone portions 326, e.g., by a blanket deposition and etch process. In an embodiment, the upper backbone portions 328 is or includes a high-k material, such as metal oxide dielectric material. In other embodiments, the upper backbone portions 328 is or includes a silicon nitride material. In another embodiment, lower backbone portions 326 are composed of silicon, oxygen and nitrogen, and upper backbone portions 328 are composed of hafnium and oxygen.

Referring to FIG. 3H, the recessed isolation structures 314B are further recessed to form recessed isolation structures 314C to form structure 399. The combination of each lower backbone portion 326 and the overlying corresponding upper backbone portion 328 forms a forksheet backbone 326/328.

It is to be appreciated that the structure 399 can be subjected to subsequent processing to form forksheet structures, such as a first forksheet structure formed from the two left-hand fins 322A and 322B, and a second forksheet structure formed from the two right-hand fins 324A and 324B, with the fins 324A/324B being relatively wider than the corresponding fins 322A/322B. Subsequent processing can include nanowire or nanoribbon 310 release by removing the sacrificial layers 312. The dielectric cap 313 can be retained or removed. A gate structure can be formed around each corresponding stack of released nanowires or nanoribbons 310. In one embodiment, the forksheet backbone 326/328 is higher than the gate structures, and the forksheet backbone 326/328 acts as an endcap for the gate structures, such as is depicted in FIG. 1B.

Referring again to FIG. 3H, an integrated circuit structure 399 includes a backbone 326/328 including a lower backbone portion 326 distinct from an upper backbone portion 328. A first vertical stack of nanowires 310 is in lateral contact with a first side of the backbone 326/328. A second vertical stack of nanowires 310 is in lateral contact with a second side of the backbone 326/328, the second side opposite the first side.

In an embodiment, a seam is vertically between the lower backbone portion 326 distinct and the upper backbone portion 328, as is depicted. In an embodiment, the lower backbone portion 326 includes silicon and oxygen, and the upper backbone portion 328 includes a metal and oxygen.

In an embodiment, the first and second vertical stacks of nanowires 310 are in lateral contact with the lower backbone portion 326 but not with the upper backbone portion 328, as is depicted. In another embodiment, however, the first and second vertical stacks of nanowires 310 are in lateral contact with both the lower backbone portion 326 and the upper backbone portion 328.

In another aspect, one or more embodiments described herein are directed to depopulation of one or more channels in a forksheet transistor. One or more embodiments described herein provide top-down channel depopulation, and one or more embodiments described herein provide bottom-up channel depopulation. One or more embodiments described herein utilize depopulated channels in integrated circuit devices, such as SRAM cells.

To provide context, forksheet transistors with different drive currents may be needed for different circuit types. Embodiments disclosed herein are directed to achieving different drive currents by depopulating the number of forksheet transistor channels in device structures. One or more embodiments provide an approach for deleting discrete numbers of wires from a forksheet transistor structure. One or more embodiments provide an approach for rendering a discrete number of wires from a forksheet transistor structure as non-conducting.

Embodiments may include channel depopulation of forksheet transistors to provide for modulation of drive currents in different devices, which may be needed for different circuits. The ability to provide modulated drive current between different forksheet transistors within a single device can allow for improved flexibility in circuit design. Exemplary depopulations schemes are described below. It is to be appreciated that although exemplified with respect to a classic nanowire stack, the processes below are suitable for a more complex forksheet stack in which nanowire or nanoribbons are adjacent a backbone structure.

In accordance with an embodiment of the present disclosure, channel processing of an alternating Si/SiGe stack includes patterning the stack into fins. Generic dummy gates (which may or may not be poly dummy gates) are patterned and etched. Source/drain regions may be formed on opposite ends of the dummy gates. The dummy gate is then removed to expose the remaining portions of the alternating Si/SiGe stack (i.e., the channel region). A pre-amorphization implantation may be implemented. Following the pre-amorphization, a depopulation dopant is implanted into the top Si layer. The pre-amorphization implantation disrupts the crystal structure of top Si layer and minimizes tunneling of subsequent dopants to lower Si layers. In this way, the top Si layer is rendered non-conducting without negatively impacting the underlying Si layers.

In accordance with an embodiment of the present disclosure, described herein is a process flow for achieving bottom-up transistor channel depopulation. Embodiments may include channel depopulation of forksheet transistors to provide for modulation of drive currents in different devices, which may be needed for different circuits.

In accordance with an embodiment of the present disclosure, processing of an alternating Si/SiGe stack includes patterning the stack into fins. Generic dummy gates (which may or may not be poly dummy gates) are patterned and etched. A hardmask or other blocking layer is deposited and recessed to below a top of a last SiGe layer on the bottom. A hard mask selective to the blocking layer is conformally deposited and slimmed to protect the top Si/SiGe layers. The blocking layer is removed and a dummy gate oxide is broken-through, exposing the bottom SiGe layer. The SiGe bottom layer is then etched away from the bottom-up and stops on the bottom Si nanowire and substrate below. The bottom Si nanowire is then etched away and stops on the next SiGe layer (and some substrate may also be etched). The sequence can then be repeated, e.g., etch SiGe, then etch Si. In this way, Si nanowires are etched away sequentially from the bottom-up.

Although the preceding processes describe using Si and SiGe layers, other pairs of semiconductor materials which can be alloyed and grown epitaxially could be implemented to achieve various embodiments herein, for example, InAs and InGaAs, or SiGe and Ge.

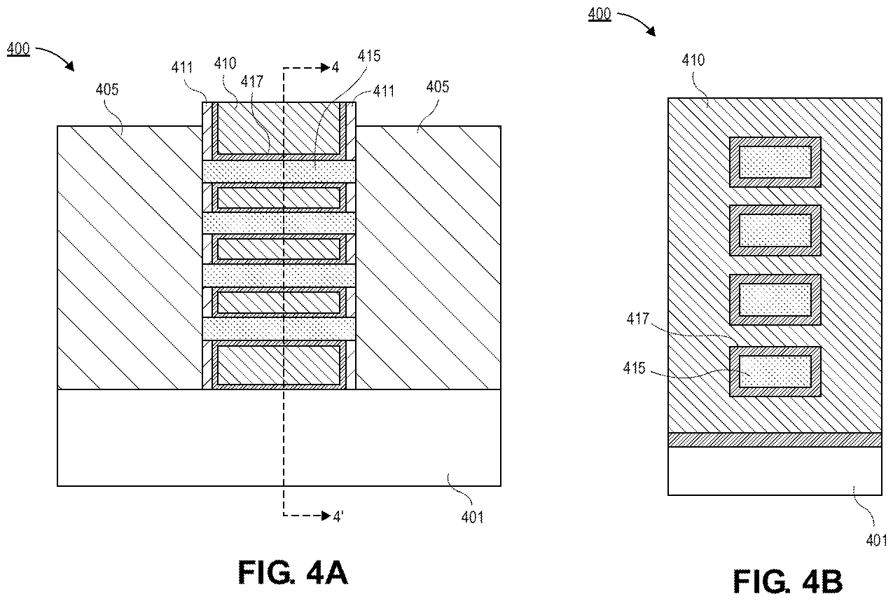

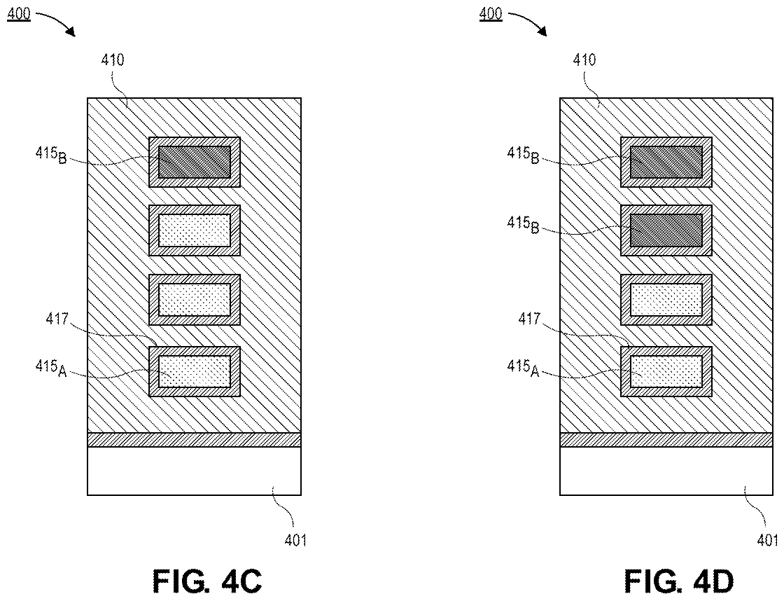

Referring now to FIG. 4A, a cross-sectional illustration of a nanowire transistor 400 is shown, in accordance with an embodiment. The nanowire transistor 400 includes a substrate 401. The substrate 401 may be an insulating material or may include an insulating material and a semiconductor material. For example, the semiconductor material may include remnant portions of a semiconductor fin, from which the transistor 400 is fabricated. In an embodiment, an underlying semiconductor substrate (not shown) that is below the substrate 401 represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as substrates including germanium, carbon, or group III-V materials.

In an embodiment, the transistor 400 may include source/drain regions 405 that are on opposite ends of a stack of nanowire channels 415. The source/drain regions 405 are formed by conventional processes. For example, recesses are formed adjacent to the gate electrode 410. These recesses may then be filled with a silicon alloy using a selective epitaxial deposition process. In some implementations, the silicon alloy may be in-situ doped silicon germanium, in-situ doped silicon carbide, or in-situ doped silicon. In alternate implementations, other silicon alloys may be used. For instance, alternate silicon alloy materials that may be used include, but are not limited to, nickel silicide, titanium silicide, cobalt silicide, and possibly may be doped with one or more of boron and/or aluminum.

In an embodiment, spacers 411 may separate the gate electrode 410 from the source/drain regions 405. The nanowire channels 415 may pass through the spacers 411 to connect to the source/drain regions 405 on either side of the nanowire channels 415. In an embodiment, a gate dielectric 417 surrounds the perimeter of the nanowire channels 415 to provide gate-all-around (GAA) control of the transistor 400. The gate dielectric 417 may be, for example, any suitable oxide such as silicon dioxide or high-k gate dielectric materials. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer 417 to improve its quality when a high-k material is used.

In an embodiment, the gate electrode 410 surrounds the gate dielectric layer 417 within the spacers 411. In the illustrated embodiment, the gate electrode 410 is shown as a single monolithic layer. However, it is to be appreciated that the gate electrode 410 may include a workfunction metal over the gate dielectric layer 417 and a gate fill metal. When the workfunction metal will serve as an N-type workfunction metal, the workfunction metal of the gate electrode 410 preferably has a workfunction that is between about 3.9 eV and about 4.2 eV. N-type materials that may be used to form the metal of the gate electrode 410 include, but are not limited to, hafnium, zirconium, titanium, tantalum, aluminum, and metal carbides that include these elements, i.e., titanium carbide, zirconium carbide, tantalum carbide, hafnium carbide and aluminum carbide. When the workfunction metal will serve as a P-type workfunction metal, workfunction metal of the gate electrode 410 preferable has a workfunction that is between about 4.9 eV and about 5.2 eV. P-type materials that may be used to form the metal of the gate electrode 410 include, but are not limited to, ruthenium, palladium, platinum, cobalt, nickel, and conductive metal oxides, e.g., ruthenium oxide.

In the illustrated embodiment, the transistor 400 is shown as having four nanowire channels 415. However, it is to be appreciated that transistors 400 may include any number of nanowire channels 415 in accordance with various embodiments. Furthermore, FIG. 4A illustrates that all of the nanowire channels 415 are functional channels. That is, each of the nanowire channels 415 is capable of conducting electricity, in order to provide a given drive current for the transistor 400.

Referring now to FIG. 4B, a cross-sectional illustration of the transistor 400 in FIG. 4A along line 4-4′ is shown, in accordance with an embodiment. As shown, all four nanowire channels 415 are illustrated with the same shading to indicate that they are all functioning channels. As will be described below, one or more of the nanowire channels 415 may be depopulated in order to modulate the drive current of the transistor 400.

Referring now to FIG. 4C, a cross-sectional illustration of a transistor 400 with a modulated drive current is shown, in accordance with an embodiment. As shown, the transistor 400 includes first nanowire channels 415_{A} and a second nanowire channel 415_{B}. In an embodiment, the second nanowire channel 415_{B} is a depopulated channel. That is, the second nanowire channel 415_{B} may not be capable of conducting current under normal operating conditions of the transistor 400. As such, the drive current of the transistor 400 is reduced compared to the drive current of the transistor 400 shown in FIG. 4A and FIG. 4B. The transistor 400 in FIG. 4C is an example of a top-down channel depopulation. That is, the depopulated second nanowire channel 415_{B} is positioned above the first nanowire channels 415_{A}, relative to the substrate 401.

In an embodiment, the depopulated second nanowire channel 415_{B} is rendered inactive due to a high concentration of a depopulation dopant. The conductivity type (e.g., N-type or P-type) of the depopulation dopant needed to prevent current from passing across the second nanowire channel 415_{B} is the opposite conductivity type of the transistor 400. For example, when the transistor is an N-type transistor, the depopulation dopant in the second nanowire channel 415_{B} is a P-type dopant (e.g., in the case of a silicon nanowire channel 415_{B}, the depopulation dopant may be boron, gallium, etc.), and when the transistor is a P-type transistor, the depopulation dopant in the second nanowire channel 415_{B} is an N-type dopant (e.g., in the case of a silicon nanowire channel 415_{B}, the depopulation dopant may be phosphorous, arsenic, etc.).

In an embodiment, a concentration of the depopulation dopant that blocks conductivity across the second nanowire channel 415_{B} may be approximately 1e19 cm⁻³ or greater, or approximately 1e20 cm⁻³ or greater. In an embodiment, the concentration of the depopulation dopant in the second nanowire channel 415_{B} may be approximately two orders of magnitude greater than the concentration of the depopulation dopant in the first nanowire channels 415_{A}, or the concentration of the depopulation dopant in the second nanowire channel 415_{B} may be approximately three orders of magnitude greater than the concentration of the depopulation dopant in the first nanowire channels 415_{A}. The concentrations of the depopulation dopant in the first nanowire channels 415_{A} is low enough that the conductivities of the first nanowire channels 415_{A} are not significantly reduced.

As will be described in greater detail below, the ability to selectively dope the second nanowire channel 415_{B} over the first nanowire channels 415_{A} is provided, at least in part, by a pre-amorphization implant. A pre-amorphization implant includes implanting a species into the second nanowire channel 415_{B} that disrupts the crystal structure of the second nanowire channel 415_{B}. That is, in some embodiments, a degree of crystallinity of the second nanowire channel 415_{B} may be lower than a degree of crystallinity of the first nanowire channels 415_{A}. Disrupting the crystal structure of the second nanowire channel 415_{B} limits subsequently implanted depopulation dopants from tunneling into the underlying first nanowire channels 415_{A}. The pre-amorphization species is an element that does not significantly alter the conductivity of the second nanowire channel 415_{B}. That is, the pre-amorphization species is substantially non-electrically active. For example, in the case of a silicon nanowire channel, the pre-amorphization species may include germanium. Accordingly, embodiments disclosed herein may also exhibit a concentration of the pre-amorphization species in the second nanowire channel 415_{B}.

As shown, the second nanowire channel 4158 may have a structure that is similar to the structure of the first nanowire channels 415_{A} (with the exception of the concentration of the depopulation dopant, the degree of crystallinity, and the concentration of the pre-amorphization species). For example, the second nanowire channels 415_{B} may be surrounded by the gate dielectric 417. Additionally, the dimensions, (e.g., channel length, thickness and/or width) of the second nanowire channel 415_{B} may be substantially similar to the dimensions of the first nanowire channels 415_{A}. Furthermore, it is to be appreciated that the base material for the second nanowire channels 415_{B} and the first nanowire channels 415_{A} may be substantially the same. For example, both may include silicon as the base material.

Referring now to FIG. 4D, a cross-sectional illustration of a transistor 400 with a modulated drive current is shown, in accordance with an additional embodiment. The transistor 400 in FIG. 4D may be substantially similar to the transistor 400 in FIG. 4C, with the exception that an additional second nanowire channel 415_{B} is provided. The two second nanowire channels 415_{B} are fabricated in a top-down configuration. That is, the second nanowire channels 415_{B} are positioned over the first nanowire channels 415_{A}, relative to the substrate 401. While transistors 400 are shown with a single depopulated second nanowire channel 415_{B} and a pair of depopulated second nanowire channels 415_{B}, it is to be appreciated that any number of nanowire channels 415 may be depopulated to provide a desired drive current for the transistor 400.

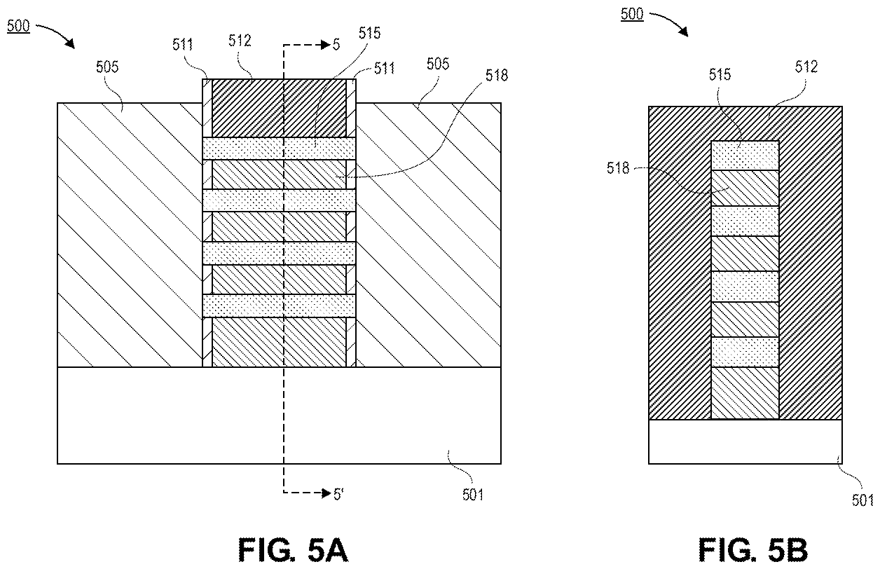

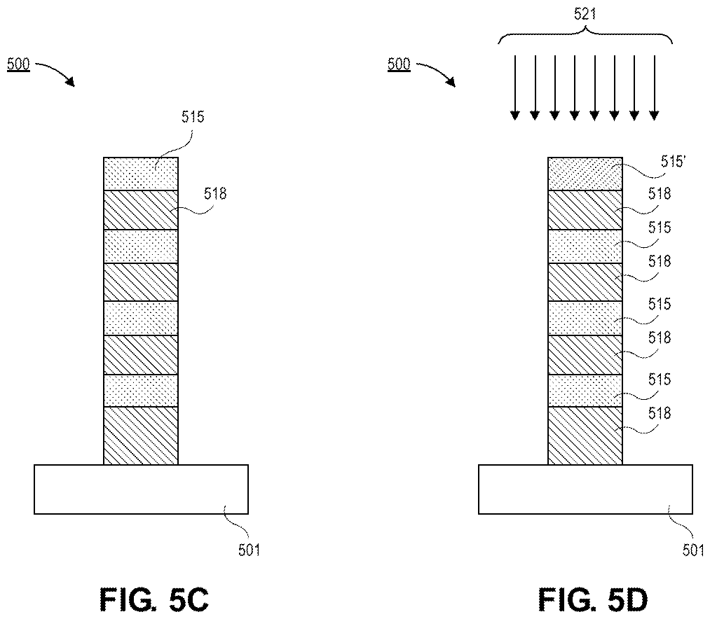

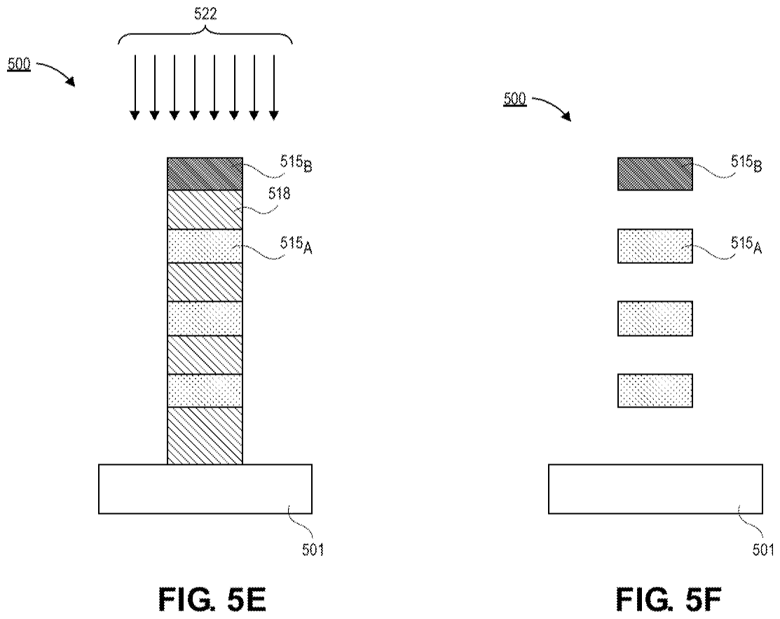

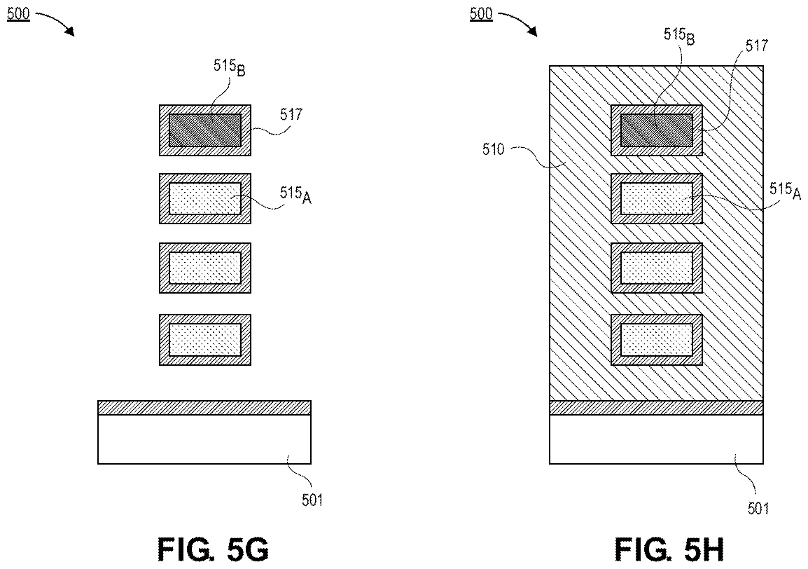

Referring now to FIGS. 5A-5H, a series of cross-sectional illustrations depict a process for forming a transistor 500 with one or more depopulated nanowire channels using a top-down depopulation approach is shown, in accordance with an embodiment.

Referring now to FIG. 5A, a cross-sectional illustration of a transistor 500 is shown, in accordance with an embodiment. In the illustrated embodiment, source/drain regions 505 have been formed on opposite ends of a gate structure over a substrate 501. The gate structure may include a dummy gate electrode 512 and spacers 511. The gate structure may cover a stack of nanowire channels 515 and sacrificial layers 518. For example, the nanowire channels 515 may include silicon and the sacrificial layers 518 may include silicon germanium, though other suitable material choices with etch selectivity between the nanowire channels 515 and the sacrificial layers 518 may be used. In an embodiment, the nanowire channels 515 extend through the spacers 511 to contact the source/drain regions 505. In an embodiment, the dummy gate electrode 512 may include polysilicon.

Referring now to FIG. 5B, a cross-sectional illustration of the transistor 500 in FIG. 5A along line 5-5′ is shown, in accordance with an embodiment. As shown, the dummy gate electrode 512 wraps around the sidewalls and top surface of the stack of nanowire channels 515 and sacrificial layers 518.

Referring now to FIG. 5C, a cross-sectional illustration of the transistor 500 after the dummy gate electrode 512 is removed is shown, in accordance with an embodiment. In an embodiment, the dummy gate electrode 512 may be removed with a suitable etching process.

Referring now to FIG. 5D, a cross-sectional illustration of the transistor 500 during a pre-amorphization implantation process is shown, in accordance with an embodiment. As shown, pre-amorphization species 521 are implanted into the stack. The implantation may be implemented with no tilt. As such, the pre-amorphization species 521 will only enter the stack through the topmost nanowire channel 515′. In an embodiment, the energy of the implantation process is chosen to isolate the majority of the pre-amorphization species 521 into the topmost nanowire channel 515′. For example, an implantation energy of the pre-amorphization species may be between approximately 1 keV and approximately 2 keV. In order to represent a change in crystallinity of the topmost nanowire channel 515′, the shading of the topmost nanowire channel 515′ is different than the shading of the underlying nanowire channels 515. In an embodiment, the pre-amorphization species 521 may include germanium or silicon.

In the illustrated embodiment, the pre-amorphization implant is isolated to the topmost nanowire channel 515′. However, it is to be appreciated that by increasing the energy of the pre-amorphization implant, additional nanowire channels 515 (from the top-down) may also be altered in order to allow for more than one nanowire channel 515 to be depopulated.

Referring now to FIG. 5E, a cross-sectional illustration of the transistor 500 during a depopulation dopant implant is shown, in accordance with an embodiment. As shown, depopulation dopants 522 are implanted into the stack. The implantation may be implemented with no tilt. As such, the depopulation dopants 522 will only enter the stack through the topmost nanowire channel 515B. In an embodiment, the depopulation dopant implant is implemented after the pre-amorphization implant without an annealing process between the two implants. As such, the disrupted crystal structure of the nanowire channel 515′ remains and limits the ability of the depopulation dopants 522 from tunneling down to lower nanowire channels 515. That is, first nanowire channels 515A have concentrations of the depopulation dopant 522 that are low enough to not alter the conductivities of the first nanowire channels 515A, and the second nanowire channel 515B (i.e., the topmost nanowire channel) has a concentration of the depopulation dopant 522 that is sufficient to prevent current from passing through the second nanowire channel 515B.

In an embodiment, a concentration of the depopulation dopant 522 of the second nanowire channel 515B may be approximately 1e19 cm⁻³ or greater, or approximately 1e20 cm⁻³ or greater. In an embodiment, the concentration of the depopulation dopant 522 in the second nanowire channel 515B may be approximately two orders of magnitude greater than the concentration of the depopulation dopant 522 in the first nanowire channels 515A, or the concentration of the depopulation dopant 522 in the second nanowire channel 515B may be approximately three orders of magnitude greater than the concentration of the depopulation dopant 522 in the first nanowire channels 515A. In an embodiment, the depopulation dopant 522 may include an N-type dopant (e.g., in the case of a silicon nanowire channel 515, phosphorous, arsenic, etc.) or a P-type dopant (e.g., in the case of a silicon nanowire channel 515, boron, gallium, etc.).

In the illustrated embodiment, the depopulation dopants 522 are substantially isolated to the topmost second nanowire channel 515B. However, it is to be appreciated that by increasing the energy of the depopulation dopant implant (in conjunction with a more aggressive pre-amorphization implant), additional nanowire channels 515 (from the top-down) may also be altered in order to allow for more than one nanowire channel 515 to be depopulated. In an embodiment, the depopulation dopant implant may have an energy between approximately 1 keV and approximately 2 keV.

Referring now to FIG. 5F, a cross-sectional illustration of the transistor 500 after the sacrificial layers 518 are removed is shown, in accordance with an additional embodiment. In an embodiment, the sacrificial layers 518 may be removed with a suitable etching process that removes the sacrificial layers 518 selective the nanowire channels 515. In an embodiment, where the sacrificial layers 518 are silicon germanium and the nanowire channels 515 are silicon, the silicon germanium layer is etched selectively with a wet etch that selectively removes the silicon germanium while not etching the silicon layers. Etch chemistries such as carboxylic acid/nitric acid/HF chemistry, and citric acid/nitric acid/HF, for example, may be utilized to selectively etch the silicon germanium.

Referring now to FIG. 5G, a cross-sectional illustration of the transistor 500 after a gate dielectric 517 is disposed over the nanowire channels 515A and 515B is shown, in accordance with an embodiment. In an embodiment, the gate dielectric 517 may be deposited with a conformal deposition process (e.g., atomic layer deposition (ALD), or the like). The gate dielectric 517 may be any suitable gate dielectric material, such as those described above.

Referring now to FIG. 5H, a cross-sectional illustration of the transistor 500 after a gate electrode 510 is disposed over the gate dielectric 517 is shown, in accordance with an embodiment. In an embodiment, the gate electrode 510 may include a workfunction metal and a fill metal. Suitable material(s) for the gate electrode 510 are provided above. As shown, the depopulated second nanowire channel 515B maintains a structure similar to the structure of the active first nanowire channels 515A. The second nanowire channel 515B is rendered non-conducting by the presence of the depopulation dopants 522. Additionally, the second nanowire channels 515B may be identified by having a degree of crystallinity that is lower than that of the first nanowire channels 515A.

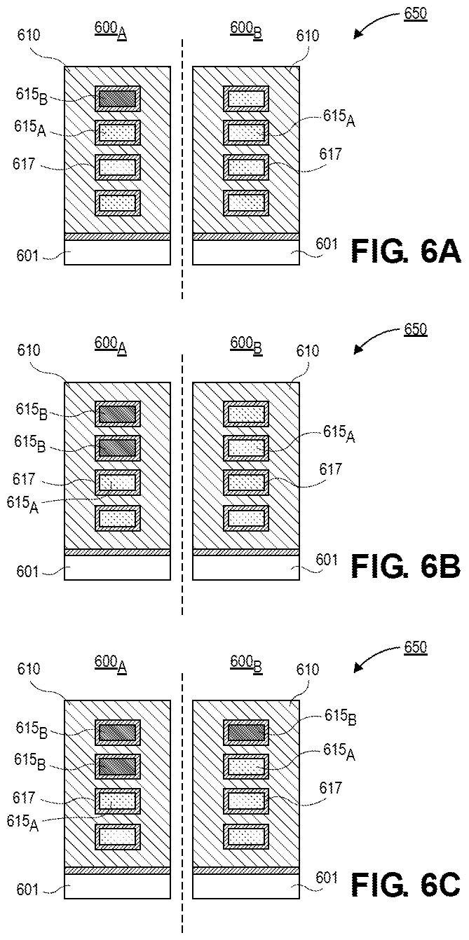

In an embodiment, in order to engineer different devices having different drive-current strengths, a top-down depopulation process flow can be implemented using lithography so that nanowire channels are depopulated only from specific devices. In an embodiment, the entire wafer may be depopulated uniformly so all devices have same number of nanowire channels. Examples of selective depopulation are shown in FIGS. 6A-6C.

Referring now to FIG. 6A, a cross-sectional illustration depicting portions of a semiconductor device 650 is shown, in accordance with an embodiment. In an embodiment, the semiconductor device 650 may include a first transistor 600_{A} and a second transistor 600_{B}. In an embodiment, individual ones of the first transistor 600_{A} and the second transistor 600_{B} may be disposed over a substrate 601 and include a plurality of nanowire channels 615 surrounded by a gate dielectric 617 and a gate electrode 610.

In an embodiment, the first transistor 600_{A} may include first nanowire channels 615_{A} and a second nanowire channel 615_{B}. The first nanowire channels 615_{A} are active channels and the second nanowire channel 615_{B} is a depopulated (i.e., non-active) channel. In the particular embodiment illustrated in FIG. 6A, there are three first nanowire channels 615_{A} and a single second nanowire channel 615_{B}. In an embodiment, the second transistor 600_{B} may include only active first nanowire channels 615_{A}. In an embodiment, the total number of nanowire channels 615 in the first transistor 600_{A} (e.g., four—three active first nanowire channels 615_{A} and one depopulated second nanowire channel 615_{B}) is equal to the number of nanowire channels 615 in the second transistor 600_{B}. Due to the lower number of active first nanowire channels 615_{A}, the drive current of the first transistor 600_{A} is lower than the drive current of the second transistor 600_{B}.

Referring now to FIG. 6B, a cross-sectional illustration depicting portions of a semiconductor device 650 is shown, in accordance with an additional embodiment. The semiconductor device 650 in FIG. 6B is substantially similar to the semiconductor device 650 in FIG. 6A, with the exception that the first transistor 600_{A} includes a pair of depopulated second nanowire channels 615_{B}. As such, an even greater difference is provided between the drive current of the first transistor 600_{A} and the drive current of the second transistor 600_{B}.

Referring now to FIG. 6C, a cross-sectional illustration depicting portions of a semiconductor device 650 is shown, in accordance with an additional embodiment. The semiconductor device 650 in FIG. 6C is substantially similar to the semiconductor device 650 in FIG. 6B, with the exception that the second transistor 600_{B} also includes a depopulated second nanowire channel 615_{B}. Accordingly, the first transistor 600_{A} and the second transistor 600_{B} may have different drive currents, as well as both transistors 600_{A} and 600_{B} having a different drive current than a transistor (not shown) without any depopulated channels. This provides further flexibility in designing circuitry of the semiconductor device 650.

In the embodiments disclosed above, a top-down depopulation scheme is described. However, embodiments are not limited to such depopulation schemes. For example, embodiments disclosed herein may also utilize a bottom-up depopulation scheme. In the bottom-up depopulation schemes described herein, the depopulated nanowire channel is completely removed from the stack of nanowire channels. This is in contrast to the top-down approach where the bulk structure of the depopulated nanowire channel is maintained while only changing electrical conductivity of the nanowire.

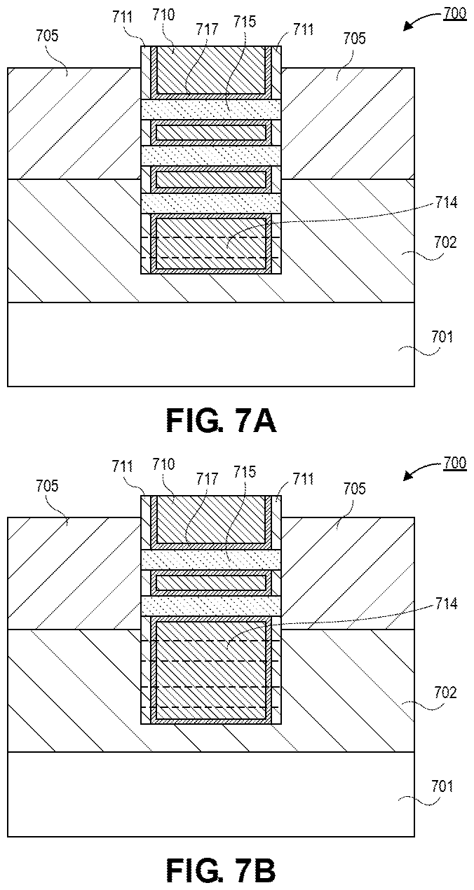

Referring now to FIG. 7A, a cross-sectional illustration of a transistor 700 formed with a bottom-up depopulation scheme is shown, in accordance with an embodiment. In an embodiment, the transistor 700 may include a substrate 701. Source/drain regions 705 may be separated from the substrate 701 by an insulator 702 and be positioned on either end of a gate stack. The gate stack may cover the nanowire channels 715 that connect the source/drain regions 705 together. The gate stack may include a gate dielectric 717 and a gate electrode 710. Spacers 711 may separate the gate electrode 710 from the source/drain regions 705. Suitable materials for the source/drain regions 705, the gate dielectric 717, and the gate electrode 710 are similar to those described above.

As shown, the stack of nanowire channels 715 includes a depopulated region 714. The depopulated region 714 (indicated with dashed lines) is the location where the bottommost semiconductor channel would otherwise be located if it was not depopulated (i.e., removed). In an embodiment, the depopulated region 714 may include portions of the gate electrode 710. Furthermore, the positioning and structure of the remaining nanowire channels 715 are not changed. That is, the spacings between the remaining nanowire channels 715 and the substrate 701 is not changed by removing one or more of the nanowire channels 715.

Referring now to FIG. 7B, a cross-sectional illustration of a transistor 700 formed with a bottom-up depopulation scheme is shown, in accordance with an additional embodiment. The transistor 700 in FIG. 7B is substantially similar to the transistor 700 in FIG. 7A, with the exception that an additional depopulated region 714 is provided. That is, two nanowire channels 715 have been depopulated (i.e., removed). While the depopulation of one and two nanowire channels 715 are shown in FIGS. 7A and 7B, respectively, it is to be appreciated that any number of nanowire channels 715 may be depopulated in order to provide a desired drive current to the transistor, in accordance with an embodiment.

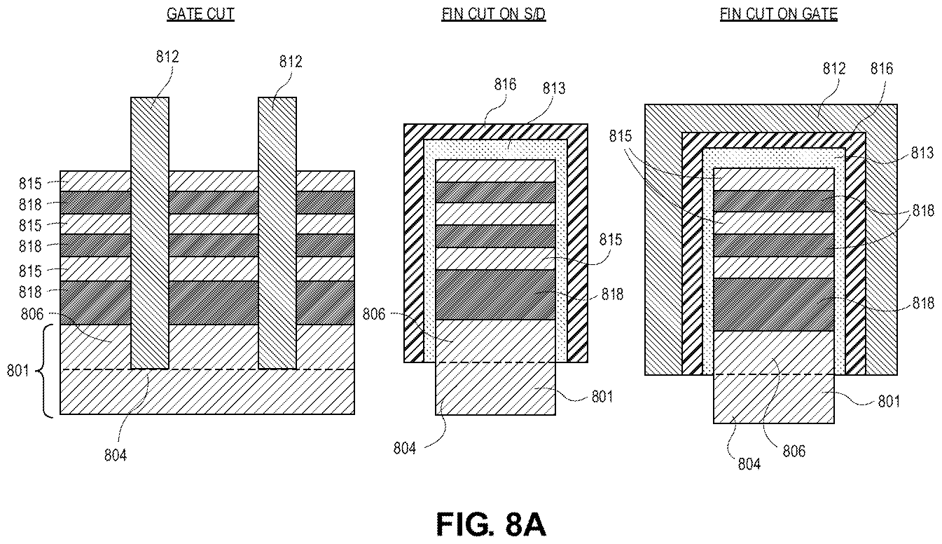

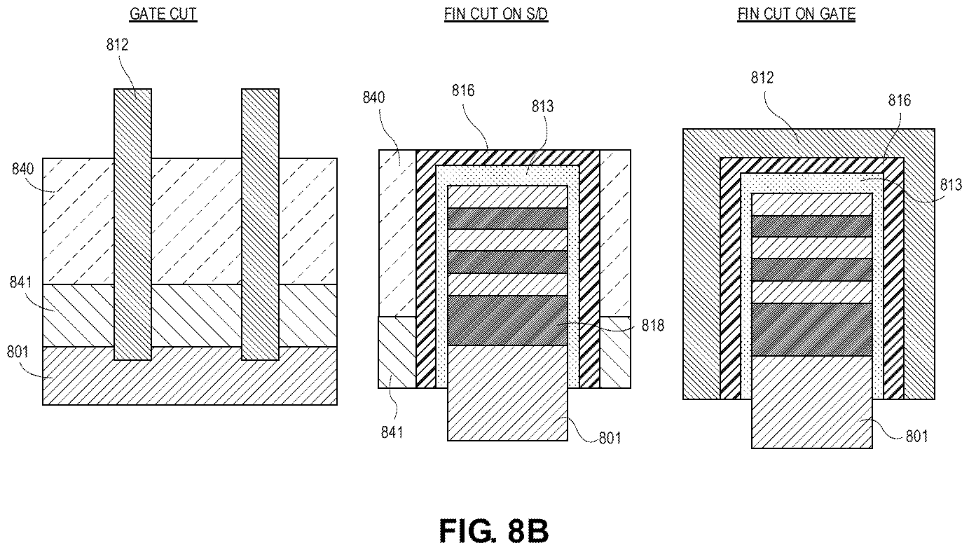

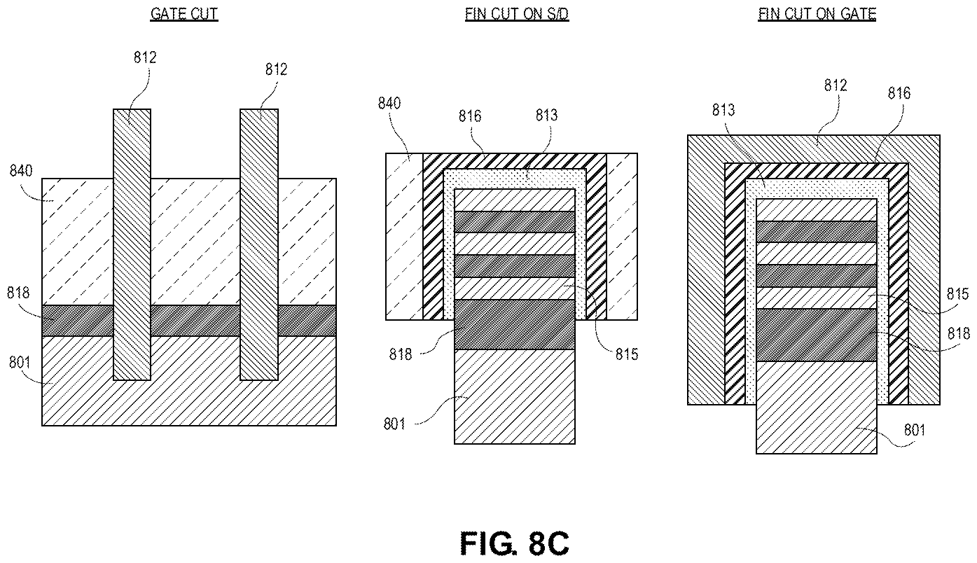

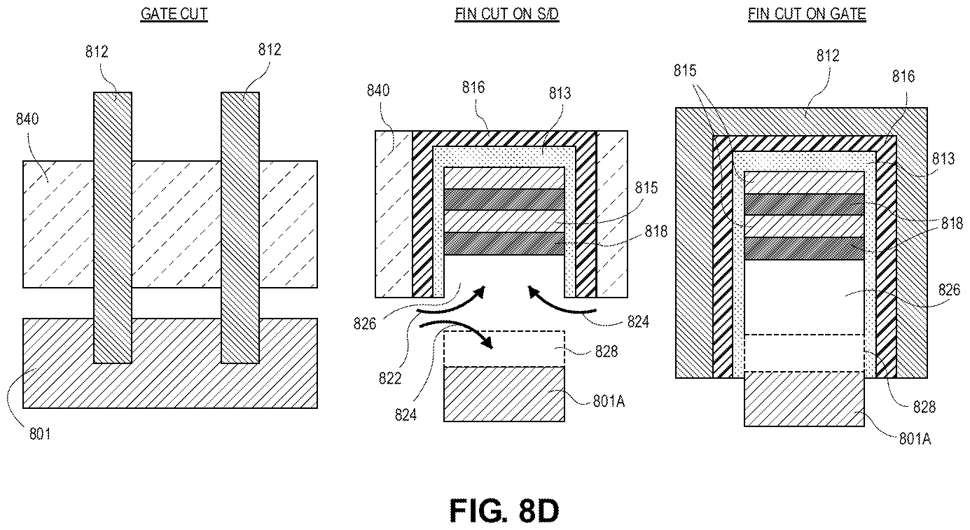

Referring now to FIGS. 8A-8D, a series of cross-sectional illustrations depicting a process for implementing a bottom-up depopulation scheme is provided, in accordance with an embodiment. For each of the FIGS. 8A, 8B, 8C and 8D, a gate cut cross-sectional view (left-hand side), a fin cut on source or drain (S/D) cross-sectional view (middle), and a fin cut on gate cross-sectional view (right-hand side), are illustrated.

Referring to FIG. 8A, a starting stack includes a fin of alternating silicon germanium layers 818 and silicon layers 815 above a substrate 801, which may be or include a silicon fin. In the case that substrate 801 includes or is a silicon fin, an upper fin portion 806 may be above a lower fin portion 804, as delineated by the height of a shallow trench isolation structure (not depicted). The silicon layers 815 may be referred to as a vertical arrangement of silicon nanowires. The bottommost silicon germanium layer 818 may be thicker than upper silicon germanium layers 818, as is depicted.

Referring again to FIG. 8A, a dielectric liner 813, such as a dummy gate oxide liner composed of silicon oxide, is over the fin of alternating silicon germanium layers 818 and silicon layers 815. A protective cap layer 816, such as a silicon nitride or titanium nitride cap layer, may be formed on the dielectric liner 813. It is to be appreciated that for clarity, the dielectric liner 813 and the protective cap layer 816 are not depicted in the gate cut image (left), but would be present over the structure. Gate stacks 812, such as sacrificial or dummy gate stacks composed of polysilicon or a silicon nitride pillar, are formed over the dielectric liner 813 and the protective cap layer 816 over the alternating silicon germanium layers 818 and silicon layers 815. Although the preceding describes using Si and SiGe layers, other pairs of semiconductor materials which can be alloyed and grown epitaxially could be implemented to achieve various embodiments herein, for example, InAs and InGaAs, or SiGe and Ge.

Referring to FIG. 8B, a masking stack is formed over the structure of FIG. 8A not covered by gate stacks 812. In an embodiment, the masking stack includes a lower layer 841 and an upper layer 840. In one embodiment, the lower layer 841 is a carbon-based hardmask layer which is deposited and then recessed to a desired level. For example, the level may be approximately aligned with the bottommost silicon germanium layer 818, as is depicted. In one embodiment, upper layer 840 is composed of a metal-based hardmask, such as a titanium nitride layer. The upper layer 840 is recessed to expose the protective cap layer 816.

Referring to FIG. 8C, the lower layer 841 of the masking stack of the structure of FIG. 8B is removed, e.g., by a selective wet etch process. Additionally, the lower portions of the dielectric liner 813 and the protective cap layer 816 exposed upon removing the lower layer 841 of the masking stack are removed, e.g., by further selective etch processes. Removal of the lower layer 841 and the lower portions of the dielectric liner 813 and the protective cap layer 816 exposes at least a portion of the bottommost silicon germanium layer 818.

Referring to FIG. 8D, the bottommost silicon germanium layer 818 is removed. The bottommost silicon germanium layer 818 may be removed by a selective etch process 822 that etches silicon germanium selective to silicon. Following removal of the bottommost silicon germanium layer 818, the bottommost silicon layer 815 is then removed. The bottommost silicon layer 815 may be removed by a selective etch process 824 that etches silicon selective to silicon germanium. The result is effective removal (or depopulation) of a bottommost silicon nanowire. It is to be appreciated that the etch 824 used to remove the bottommost silicon layer 815 may remove a portion 828 of the substrate of fin 801 to leave a partially etched fin or substrate 801A, as is depicted. Also, in an embodiment, the above process may be repeated to remove the next bottommost wire, and so on, until desired depopulation is achieved.

In an embodiment, the silicon germanium layer is etched selectively with a wet etch that selectively removes the silicon germanium while not etching the silicon layers. Etch chemistries such as carboxylic acid/nitric acid/HF chemistry, and citric acid/nitric acid/HF, for example, may be utilized to selectively etch the silicon germanium. In an embodiment, silicon layers are etched selectively with a wet etch that selectively removes the silicon while not etching the silicon germanium layers. Etch chemistries such as aqueous hydroxide chemistries, including ammonium hydroxide and potassium hydroxide, for example, may be utilized to selectively etch the silicon. Halide-based dry etches or plasma-enhanced vapor etches may also be used to achieve the embodiments herein.

It is to be appreciated that following the processing described in association with FIG. 8D, an insulating or dielectric material (shown in FIG. 5A and FIG. 5B as insulator 502) may be formed in the location 826 where channel depopulation is performed. Also, a permanent gate dielectric and a permanent gate electrode may be formed upon removal of gate structures 812.

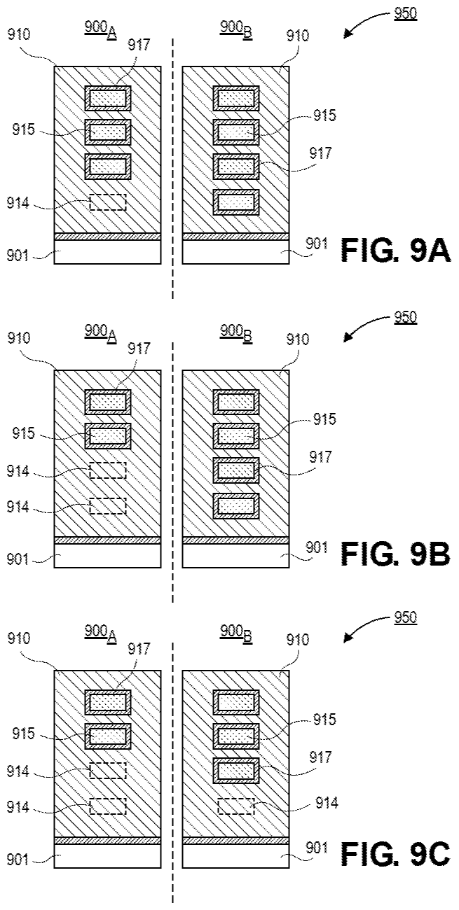

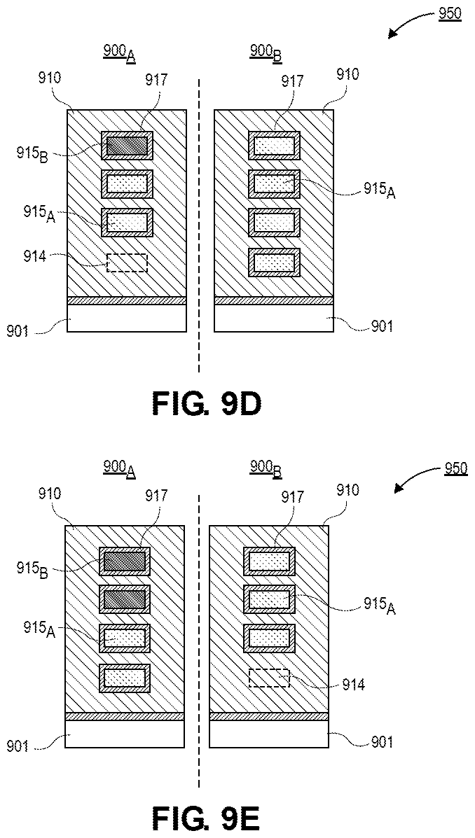

In an embodiment, in order to engineer different devices having different drive-current strengths, a bottom-up depopulation process flow can be patterned with lithography so that nanowire channels are depopulated only from specific devices. In an embodiment, the entire wafer may be depopulated uniformly so all devices have same number of nanowire channels. Examples of selective depopulation are provide in FIGS. 9A-9C.

Referring now to FIG. 9A, a cross-sectional illustration depicting portions of a semiconductor device 950 is shown, in accordance with an embodiment. In an embodiment, the semiconductor device 950 may include a first transistor 900_{A} and a second transistor 900_{B}. In an embodiment, individual ones of the first transistor 900_{A} and the second transistor 900_{B} may be disposed over a substrate 901 and include a plurality of nanowire channels 915 surrounded by a gate dielectric 917 and a gate electrode 910.

In an embodiment, the first transistor 900_{A} may include three nanowire channels 915, and the second transistor 900_{B} may include four nanowire channels 915. Having fewer nanowire channels 915 results in the first transistor 900_{A} having a lower drive current than second transistor 900_{B}. In the first transistor 900_{A} a depopulated region 914 is positioned below the three nanowire channels 915. The depopulated region 914 is aligned in the Z-direction with the bottommost nanowire channel 915 of the second transistor 900_{B}. The remaining nanowire channels 915 of the first transistor 900_{A} are each aligned (in the Z-direction) with one of the nanowire channels 915 of the second transistor 900_{B}. For example, the topmost nanowire channel 915 in the first transistor 900_{A} is aligned with the topmost nanowire channel 915 in the second transistor 900_{B}.

Referring now to FIG. 9B, a cross-sectional illustration depicting portions of a semiconductor device 950 is shown, in accordance with an additional embodiment. The semiconductor device 950 in FIG. 9B is substantially similar to the semiconductor device 950 in FIG. 9A, with the exception that the first transistor 900_{A} includes a pair of depopulated regions 914. As such, an even greater difference is provided between the drive current of the first transistor 900_{A} and the drive current of the second transistor 900_{B}.

Referring now to FIG. 9C, a cross-sectional illustration depicting portions of a semiconductor device 950 is shown, in accordance with an additional embodiment. The semiconductor device 950 in FIG. 9C is substantially similar to the semiconductor device 950 in FIG. 9B, with the exception that the second transistor 900_{B} also includes a depopulated region 914. Accordingly, the first transistor 900_{A} and the second transistor 900_{B} may have different drive currents, as well as both transistors 900_{A} and 900_{B} having a different drive current than a transistor (not shown) without any depopulated regions. This provides further flexibility in designing circuitry of the semiconductor device 950.

In the embodiments described above the depopulation architectures were described as including either top-down or bottom-up process flows. However, it is to be appreciated that in some embodiments a combination of both process flow may be provided. Examples of such semiconductor device 950 are provided in FIGS. 9D and 9E.

Referring now to FIG. 9D, a cross-sectional illustration of a semiconductor device 950 is shown, in accordance with an embodiment. In an embodiment, the semiconductor device 950 includes a first transistor 900_{A} and a second transistor 900_{B}. The second transistor 900_{B} includes only active first nanowire channels 915A. The first transistor 900_{A} may include active first nanowire channels 915A, a depopulated second nanowire channel 915B, and a depopulated region 914. For example, the depopulated second nanowire channel 9158 may be doped with a depopulation dopant (e.g., using a top-down process flow), and the depopulated region 914 may be formed using a bottom-up process flow.

Referring now to FIG. 9E, a cross-sectional illustration of a semiconductor device 950 is shown, in accordance with an additional embodiment. In an embodiment, the first transistor 900_{A} may include one or more depopulated second nanowire channels 915B, and the second transistor 900_{B} may include one or more depopulated regions 914. That is, within a single device, individual transistors 900 may be depopulated using either a top-down process flow or a bottom-up process flow.

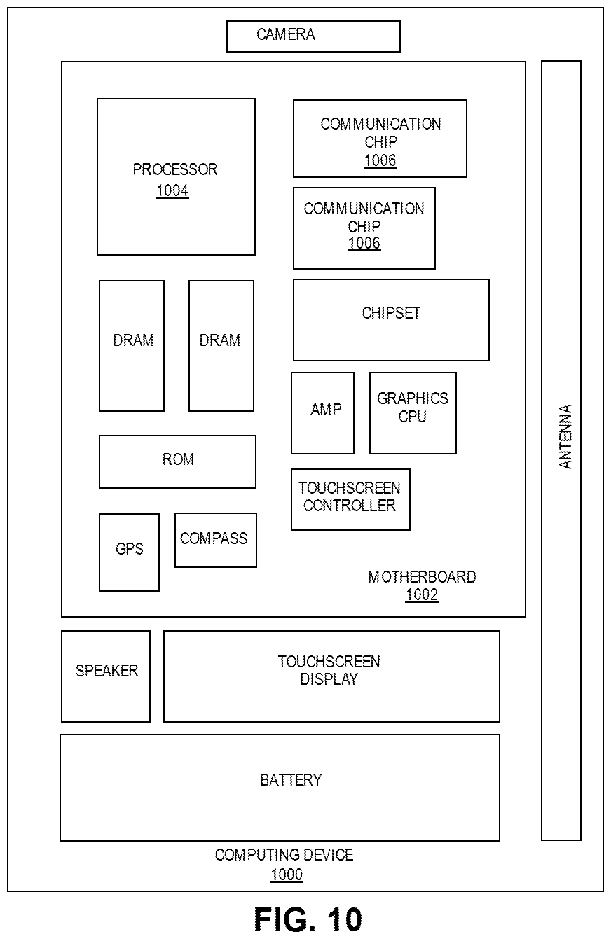

FIG. 10 illustrates a computing device 1000 in accordance with one implementation of an embodiment of the disclosure. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

Depending on its applications, computing device 1000 may include other components that may or may not be physically and electrically coupled to the board 1002. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In an embodiment, the integrated circuit die of the processor 1004 may include forksheet transistors with self-aligned backbones, such as those described herein. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In an embodiment, the integrated circuit die of the communication chip 1006 may include forksheet transistors with self-aligned backbones, such as those described herein.

In further implementations, another component housed within the computing device 1000 may include forksheet transistors with self-aligned backbones, such as those described herein.

In various implementations, the computing device 1000 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1000 may be any other electronic device that processes data.

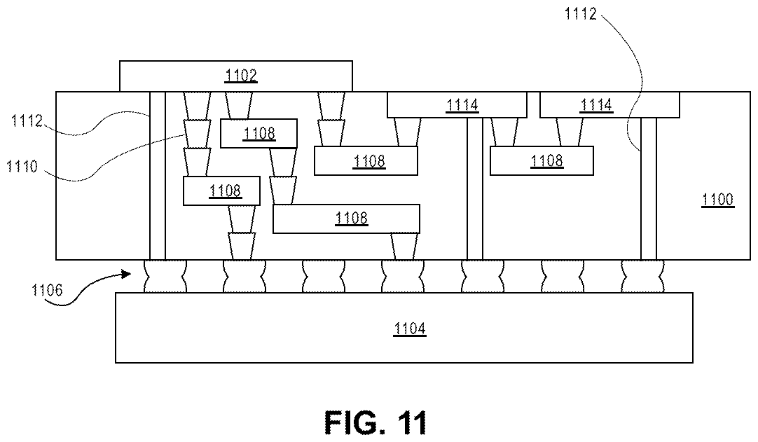

FIG. 11 illustrates an interposer 1100 that includes one or more embodiments of the disclosure. The interposer 1100 is an intervening substrate used to bridge a first substrate 1102 to a second substrate 1104. The first substrate 1102 may be, for instance, an integrated circuit die. The second substrate 1104 may be, for instance, a memory module, a computer motherboard, or another integrated circuit die. In an embodiment, one of both of the first substrate 1102 and the second substrate 1104 may include forksheet transistors with self-aligned backbones, in accordance with embodiments described herein. Generally, the purpose of an interposer 1100 is to spread a connection to a wider pitch or to reroute a connection to a different connection. For example, an interposer 1100 may couple an integrated circuit die to a ball grid array (BGA) 1106 that can subsequently be coupled to the second substrate 1104. In some embodiments, the first and second substrates 1102/1104 are attached to opposing sides of the interposer 1100. In other embodiments, the first and second substrates 1102/1104 are attached to the same side of the interposer 1100. And in further embodiments, three or more substrates are interconnected by way of the interposer 1100.

The interposer 1100 may be formed of an epoxy resin, a fiberglass-reinforced epoxy resin, a ceramic material, or a polymer material such as polyimide. In further implementations, the interposer 1100 may be formed of alternate rigid or flexible materials that may include the same materials described above for use in a semiconductor substrate, such as silicon, germanium, and other group III-V and group IV materials

The interposer 1100 may include metal interconnects 1108 and vias 1110, including but not limited to through-silicon vias (TSVs) 1112. The interposer 1100 may further include embedded devices 1114, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1100. In accordance with embodiments of the disclosure, apparatuses or processes disclosed herein may be used in the fabrication of interposer 1100.

Thus, embodiments of the present disclosure may include forksheet transistors with self-aligned backbones, and methods of fabricating forksheet transistors with self-aligned backbones.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example embodiment 1: An integrated circuit structure includes a backbone including a lower backbone portion distinct from an upper backbone portion. A first vertical stack of nanowires is in lateral contact with a first side of the backbone. A second vertical stack of nanowires is in lateral contact with a second side of the backbone, the second side opposite the first side.

Example embodiment 2: The integrated circuit structure of example embodiment 1, wherein a seam is vertically between the lower backbone portion distinct and the upper backbone portion.

Example embodiment 3: The integrated circuit structure of example embodiment 1 or 2, wherein the lower backbone portion includes silicon and nitrogen, and the upper backbone portion includes silicon and oxygen.

Example embodiment 4: The integrated circuit structure of example embodiment 1, 2 or 3, wherein the first and second vertical stacks of nanowires are in lateral contact with the lower backbone portion but not with the upper backbone portion.

Example embodiment 5: The integrated circuit structure of example embodiment 1, 2 or 3, wherein the first and second vertical stacks of nanowires are in lateral contact with both the lower backbone portion and the upper backbone portion.

Example embodiment 6: An integrated circuit structure includes an NMOS device including a first vertical stack of nanowires above a P-well in a first sub-fin structure. The integrated circuit structure also includes a PMOS device including a second vertical stack of nanowires above an N-well in a second sub-fin structure. The integrated circuit structure also includes a backbone laterally between the NMOS device and the PMOS device. The backbone includes a lower backbone portion distinct from an upper backbone portion. The first vertical stack of nanowires is in lateral contact with a first side of the backbone. The second vertical stack of nanowires is in lateral contact with a second side of the backbone, the second side opposite the first side.

Example embodiment 7: The integrated circuit structure of example embodiment 6, wherein a seam is vertically between the lower backbone portion distinct and the upper backbone portion.

Example embodiment 8: The integrated circuit structure of example embodiment 6 or 7, wherein the lower backbone portion includes silicon and nitrogen, and the upper backbone portion includes silicon and oxygen.

Example embodiment 9: The integrated circuit structure of example embodiment 6, 7 or 8, wherein the first and second vertical stacks of nanowires are in lateral contact with the lower backbone portion but not with the upper backbone portion.

Example embodiment 10: The integrated circuit structure of example embodiment 6, 7 or 8, wherein the first and second vertical stacks of nanowires are in lateral contact with both the lower backbone portion and the upper backbone portion.

Example embodiment 11: A computing device includes a board, and a component coupled to the board. The component includes an integrated circuit structure including a backbone including a lower backbone portion distinct from an upper backbone portion. A first vertical stack of nanowires is in lateral contact with a first side of the backbone. A second vertical stack of nanowires is in lateral contact with a second side of the backbone, the second side opposite the first side.

Example embodiment 12: The computing device of example embodiment 11, further including a memory coupled to the board.

Example embodiment 13: The computing device of example embodiment 11 or 12, further including a communication chip coupled to the board.

Example embodiment 14: The computing device of example embodiment 11, 12 or 13, further including a camera coupled to the board.

Example embodiment 15: The computing device of example embodiment 11, 12, 13 or 14, wherein the component is a packaged integrated circuit die.

Example embodiment 16: A computing device includes a board, and a component coupled to the board. The component includes an integrated circuit structure including an NMOS device including a first vertical stack of nanowires above a P-well in a first sub-fin structure. The integrated circuit structure also includes a PMOS device including a second vertical stack of nanowires above an N-well in a second sub-fin structure. The integrated circuit structure also includes a backbone laterally between the NMOS device and the PMOS device. The backbone includes a lower backbone portion distinct from an upper backbone portion. The first vertical stack of nanowires is in lateral contact with a first side of the backbone. The second vertical stack of nanowires is in lateral contact with a second side of the backbone, the second side opposite the first side.

Example embodiment 17: The computing device of example embodiment 16, further including a memory coupled to the board.

Example embodiment 18: The computing device of example embodiment 16 or 17, further including a communication chip coupled to the board.

Example embodiment 19: The computing device of example embodiment 16, 17 or 18, further including a camera coupled to the board.

Example embodiment 20: The computing device of example embodiment 16, 17, 18 or 19, wherein the component is a packaged integrated circuit die.

What is claimed is:

1. An integrated circuit structure, comprising:
a backbone comprising a lower backbone portion distinct from an upper backbone portion;
a first vertical stack of nanowires in lateral contact with a first side of the backbone; and
a second vertical stack of nanowires in lateral contact with a second side of the backbone, the second side opposite the first side.

2. The integrated circuit structure of claim 1, wherein a seam is vertically between the lower backbone portion distinct and the upper backbone portion.

3. The integrated circuit structure of claim 1, wherein the lower backbone portion comprises silicon and oxygen, and the upper backbone portion comprises a metal and oxygen.

4. The integrated circuit structure of claim 1, wherein the first and second vertical stacks of nanowires are in lateral contact with the lower backbone portion but not with the upper backbone portion.

5. The integrated circuit structure of claim 1, wherein the first and second vertical stacks of nanowires are in lateral contact with both the lower backbone portion and the upper backbone portion.

6. An integrated circuit structure, comprising:
an NMOS device including a first vertical stack of nanowires above a P-well in a first sub-fin structure;
a PMOS device including a second vertical stack of nanowires above an N-well in a second sub-fin structure; and
a backbone laterally between the NMOS device and the PMOS device, the backbone comprising a lower backbone portion distinct from an upper backbone portion, wherein the first vertical stack of nanowires is in lateral contact with a first side of the backbone, and the second vertical stack of nanowires is in lateral contact with a second side of the backbone, the second side opposite the first side.

7. The integrated circuit structure of claim 6, wherein a seam is vertically between the lower backbone portion distinct and the upper backbone portion.

8. The integrated circuit structure of claim 6, wherein the lower backbone portion comprises silicon and oxygen, and the upper backbone portion comprises a metal and oxygen.

9. The integrated circuit structure of claim 6, wherein the first and second vertical stacks of nanowires are in lateral contact with the lower backbone portion but not with the upper backbone portion.

10. The integrated circuit structure of claim 6, wherein the first and second vertical stacks of nanowires are in lateral contact with both the lower backbone portion and the upper backbone portion.

11. A computing device, comprising:
a board; and
a component coupled to the board, the component including an integrated circuit structure, comprising:
a backbone comprising a lower backbone portion distinct from an upper backbone portion;
a first vertical stack of nanowires in lateral contact with a first side of the backbone; and
a second vertical stack of nanowires in lateral contact with a second side of the backbone, the second side opposite the first side.

12. The computing device of claim 11, further comprising:
a memory coupled to the board.

13. The computing device of claim 11, further comprising:
a communication chip coupled to the board.

14. The computing device of claim 11, further comprising:
a camera coupled to the board.

15. The computing device of claim 11, wherein the component is a packaged integrated circuit die.

16. A computing device, comprising:
a board; and
a component coupled to the board, the component including an integrated circuit structure, comprising:
an NMOS device including a first vertical stack of nanowires above a P-well in a first sub-fin structure;
a PMOS device including a second vertical stack of nanowires above an N-well in a second sub-fin structure; and
a backbone laterally between the NMOS device and the PMOS device, the backbone comprising a lower backbone portion distinct from an upper backbone portion, wherein the first vertical stack of nanowires is in lateral contact with a first side of the backbone, and the second vertical stack of nanowires is in lateral contact with a second side of the backbone, the second side opposite the first side.

17. The computing device of claim 16, further comprising:
a memory coupled to the board.

18. The computing device of claim 16, further comprising:
a communication chip coupled to the board.

19. The computing device of claim 16, further comprising:
a camera coupled to the board.

20. The computing device of claim 16, wherein the component is a packaged integrated circuit die.
